(19) United States
(12) Patent Application Publication
(10) Pub. No.: US 2026/0204296 A1
(43) Pub. Date: Jul. 16, 2026

(54) STORAGE DEVICE INCLUDING RING WIRE, AND METHOD OF OPERATING THE SAME

(71) Applicant: Samsung Electronics Co., Ltd., Suwon-si (KR)

(72) Inventor: Kwangsoo Park, Suwon-si (KR)

(21) Appl. No.: 19/275,516

(22) Filed: Jul. 21, 2025

(30) Foreign Application Priority Data
Jan. 15, 2025 (KR) 10-2025-0005895

(51) Int. Cl. G11C 5/06; G11C 5/02; G11C 11/409

(52) U.S. Cl. CPC G11C 5/06; G11C 5/025; G11C 11/409

(57) ABSTRACT

A storage device includes a ring wire, a device controller connected to a main branch point of the ring wire, a first memory device connected to a first branch point of the ring wire, and a second memory device connected to a second branch point of the ring wire.

### CROSS-REFERENCE TO RELATED APPLICATION(S)

This application claims priority under 35 U.S.C. § 119 to Korean Patent Application No. 10-2025-0005895 filed on Jan. 15, 2025, in the Korean Intellectual Property Office, the disclosures of which are incorporated by reference herein in their entireties.

### BACKGROUND

A memory device stores data in response to a write request and outputs data stored therein in response to a read request. For example, the memory device is classified as a volatile memory device, which loses data stored therein when a power is turned off, such as a dynamic random access memory (DRAM) device or a static RAM (SRAM) device, or a non-volatile memory device, which retains data stored therein even when a power is turned off, such as a flash memory device, a phase-change RAM (PRAM), a magnetic RAM (MRAM), or a resistive RAM (RRAM).

The non-volatile memory device may be used in a storage device storing a large amount of data. Nowadays, as the storage capacity of the storage device increases, the storage device may be designed to include a plurality of non-volatile memory devices for providing the increased storage capacity. The plurality of non-volatile memory devices may physically share a wire for transmitting a signal. When a signal is branched or reflected on the wire, the signal may experience distortion.

### SUMMARY

In general, the present disclosure is directed toward a storage device including a ring wire and a method of operating the same.

According to some implementations, the present disclosure is directed to a storage device that includes a ring wire, a device controller connected to a main branch point of the ring wire, a first memory device connected to a first branch point of the ring wire, and a second memory device connected to a second branch point of the ring wire.

According to some implementations, the present disclosure is directed to a storage device that includes a device controller including a first channel controller and a second channel controller, a first ring wire including a first main branch point connected to the first channel controller, a first memory device connected to a first branch point of the first ring wire, a second memory device connected to a second branch point of the first ring wire, a second ring wire including a second main branch point connected to the second channel controller, a third memory device connected to a third branch point of the second ring wire, and a fourth memory device connected to a fourth branch point of the second ring wire.

According to some implementations, the present disclosure is directed to a method of operating a storage device that includes a ring wire, a device controller, a first memory device, and a second memory device includes providing, by the device controller, a first command to the first memory device, generating, by the device controller, a first data signal corresponding to the first command, providing, by the device controller, the first memory device with a branched first component of the first data signal through a first path on the ring wire, the ring wire including a main branch point connected to the device controller, a first branch point connected to the first memory device, and a second branch point connected to the second memory device and the first path bypassing the second branch point, and providing, by the device controller, the first memory device with a branched second component of the first data signal through a second path on the ring wire, the second path including the second branch point.

According to some implementations, the present disclosure is directed to a storage device that includes a ring wire, a first device connected to a first branch point of the ring wire, a second device connected to a second branch point of the ring wire, and a third device connected to a third branch point of the ring wire.

### BRIEF DESCRIPTION OF THE DRAWINGS

Example implementations will be more clearly understood from the detailed explanations.

FIG. 1 is a block diagram of an example of an electronic device according to some implementations.

FIG. 2 is a block diagram illustrating an example of a storage controller of FIG. 1 according to some implementations.

FIG. 3 is a block diagram describing a comparative example of a storage device.

FIG. 4 is a block diagram describing an example of a storage device according to some implementations.

FIG. 5 is a graph describing an example of an eye window of a storage device according to some implementations.

FIG. 6 is a graph describing an example of a detected signal of a storage device according to some implementations.

FIG. 7 is a diagram describing an example of a storage device according to some implementations.

FIG. 8 is a diagram describing an example of a storage device according to some implementations.

FIG. 9 is a diagram describing an example of a storage device according to some implementations.

FIG. 10 is a diagram describing an example of a storage device according to some implementations.

FIG. 11 is a diagram describing an example of a storage device according to some implementations.

FIG. 12 is a diagram describing an example of a storage device according to some implementations.

FIG. 13 is a diagram describing an example of a storage device according to some implementations.

FIG. 14 is a diagram describing an example of a storage device according to some implementations.

FIG. 15 is a flowchart describing a method of operating a storage device according to some implementations.

FIG. 16 is a diagram describing an example of a storage device according to some implementations.

### DETAILED DESCRIPTION

Hereinafter, example implementations will be explained in detail with reference to the accompanying drawings.

As used herein, each of the phrases such as “A or B”, “at least one of A or B”, “at least one of A or B”, “at least one of A, B, or C”, “at least one of A, B, and C”, and “at least one of B or C”, including the claims, may include any one of items listed together in the corresponding phrase, or all possible combinations thereof. Further, as used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

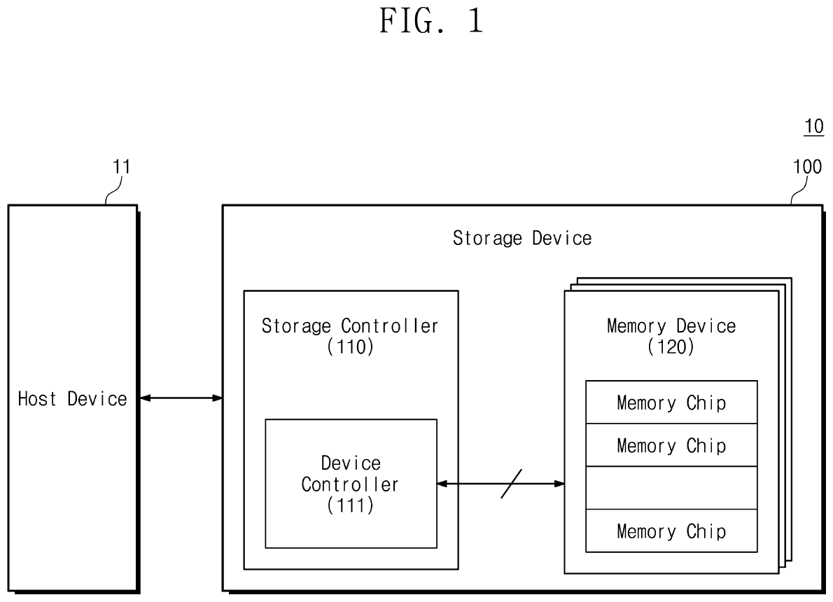

FIG. 1 is a block diagram of an example of an electronic device according to some implementations. In FIG. 1, an electronic device 10 may include an electronic system configured to process a variety of information or to store the processed information as data. For example, the electronic device 10 may be implemented with a storage system, a server system, a database server, etc. for managing a large amount of user data. In some implementations, the electronic device 10 may be implemented with a computing system, which is configured to process a variety of information, such as a personal computer (PC), a desktop, a laptop, a server, a workstation, a tablet PC, a smartphone, a digital camera, and a black box.

A host device 11 may control all operations of the electronic device 10. For example, the host device 11 may store data in a storage device 100, may read data stored in the storage device 100, or may delete data stored in the storage device 100.

For example, the host device 11 may include a central processing unit (CPU), a graphic processing unit (GPU), a neural processing unit (NPU), etc.

The storage device 100 may include a storage controller 110 and a plurality of memory devices 120. Under control of the host device 11, the storage controller 110 may store data in the memory device 120, may provide the stored data to the host device 11, or may delete the stored data.

The storage controller 110 may include a device controller 111. The device controller 111 may control the plurality of memory devices 120. The device controller 111 may be also referred to as a “controller package”. For example, the device controller 111 may manage or perform a read operation, a write operation, and an erase operation of each of the plurality of memory devices 120. Also, the device controller 111 may manage or perform a device initialization operation, a wear-leveling operation, and a garbage collection operation of each of the plurality of memory devices 120. In some implementations, the device controller 111 may support a NAND interface.

The plurality of memory devices 120 may store data under control of the storage controller 110. The memory device 120 may be implemented with a non-volatile memory device which retains data stored therein when a power is turned off. For example, the non-volatile memory device may include a NAND (not and)-based flash memory device, a NOR (not or)-based flash memory device, a phase-change RAM (PRAM), a magnetic RAM (MRAM), a resistive RAM (RRAM), etc.

Each of the plurality of memory devices 120 may include a plurality of memory chips packaged. The memory chip may be referred to as a “flash memory chip”, a “NAND chip”, or a “NAND flash memory chip”. The memory device 120 may be referred to as a “memory package”.

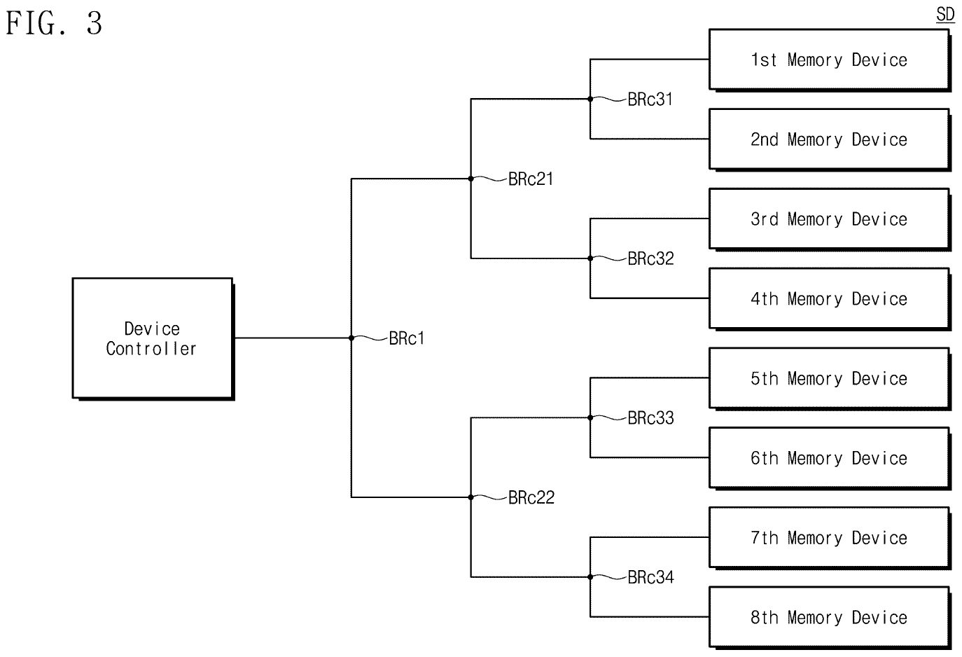

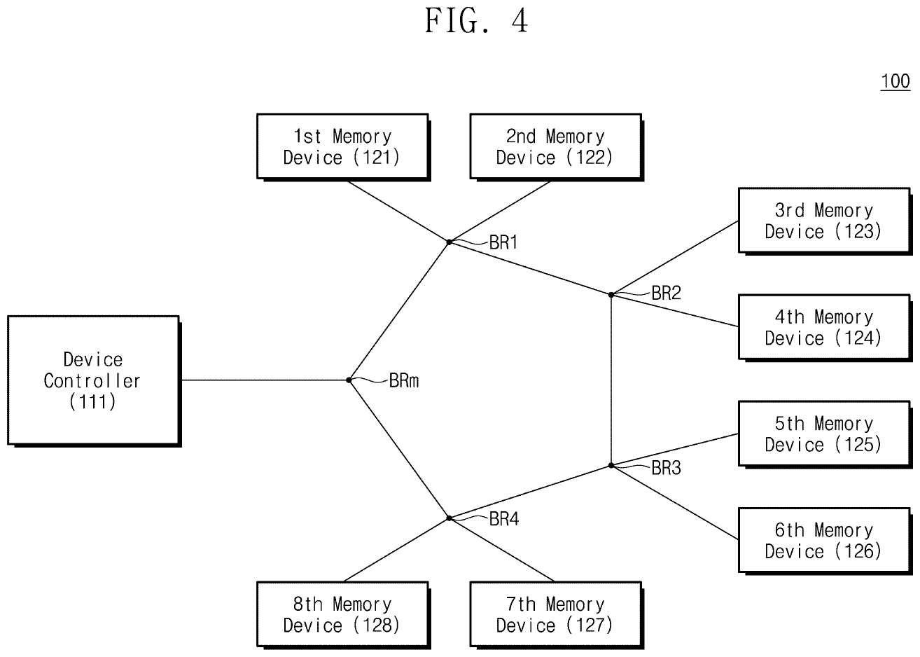

As described above, according to some implementations, one device controller 111 may manage the plurality of memory devices 120. The device controller 111 may transmit a signal (e.g., a data signal) to a target memory device among the plurality of memory devices 120 through a wire. The plurality of memory devices 120 may physically share a wire for transmitting a signal. When a signal is branched on the wire or is reflected from any other memory device on the wire, the signal may experience distortion. This will be described in detail with reference to FIGS. 3 and 4.

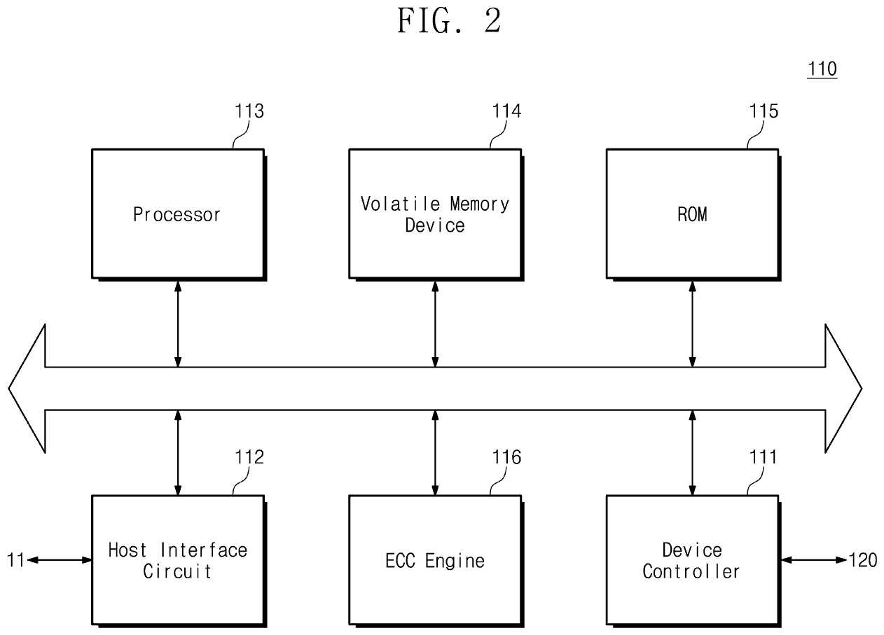

FIG. 2 is a block diagram illustrating an example of a storage controller of FIG. 1 according to some implementations. In FIGS. 1 and 2, the storage controller 110 may include the device controller 111, a host interface circuit 112, a processor 113, a volatile memory device 114, a read only memory (ROM) 115, and an error correction code (ECC) engine 116. The characteristics of the device controller 111 are similar to those of the device controller 111 of FIG. 1, and thus, additional description will be omitted to avoid redundancy.

The host interface circuit 112 may support an interface between the host device 11 and the storage device 100. The storage controller 110 may communicate with the host device 11 through the host interface circuit 112. In some implementations, the host interface circuit 112 may be implemented based on at least one of various interfaces, such as a serial ATA (SATA) interface, a peripheral component interconnect express (PCIe) interface, a serial attached SCSI (SAS), a non-volatile memory express (NVMe) interface, and a universal flash storage (UFS) interface.

The processor 113 may control all operations of the storage controller 110. The processor 113 may be referred to as an “embedded processor” of the storage controller 110. The processor 113 may drive a firmware module or of software module by executing instructions loaded to the volatile memory device 114. The processor 113 may communicate with the host device 11 through the host interface circuit 112. The processor 113 may manage the device controller 111.

The volatile memory device 114 may be a memory device which loses data stored therein when a power is turned off. The volatile memory device 114 may be implemented with a dynamic random access memory (DRAM), a static DRAM (SRAM), etc. The volatile memory device 114 may function as a buffer memory, a logical-to-physical (L2P) mapping table, or a firmware memory. The ROM 115 may store information necessary for the operation of the storage controller 110.

The ECC engine 116 may perform an error correction operation within the error correction capability. The device controller 111 may communicate with the ECC engine 116. For example, the device controller 111 may store data encoded by the ECC engine 116 in the memory devices 120. The device controller 111 may read the data from the memory devices 120 and may perform an error correction operation by decoding the read data by using the ECC engine 116. An error which does not exceed the error correction capability (e.g., error bits, the number of which does not exceed the maximum number of error bits correctable by the ECC engine 116) may be restored by the error correction operation.

FIG. 3 is a block diagram describing a comparative example of a storage device. Referring to FIG. 3, a comparative storage device SD may connect a plurality of memory devices to one device controller to provide a large storage capacity. For example, the storage device SD may include the device controller and first to eighth memory devices. The device controller may be connected to the first to eighth memory devices through a wire of a continuous T-shaped branch structure.

Below, for better understanding of the present disclosure, characteristics of the storage device SD will be described, but the storage device SD may include technical characteristics not disclosed in documents of the information disclosure statement (IDS). The description of the storage device SD is not intended to limit the scope of the present disclosure.

The device controller may be connected to the first to eighth memory devices sequentially through a first branch, a second branch, and a third branch. The first branch may correspond to a branch point BRc1. The second branch may correspond to a branch point BRc21 and a branch point BRc22. The third branch may correspond to a branch point BRc31, a branch point BRc32, a branch point BRc33, and a branch point BRc34.

The device controller may be directly connected to the branch point BRc1. The branch point BRcl may be directly connected to the branch point BRc21 and the branch point BRc22. The branch point BRc21 may be directly connected to the branch point BRc31 and the branch point BRc32. The branch point BRc22 may be directly connected to the branch point BRc33 and the branch point BRc34.

The first and second memory devices may be directly connected to the branch point BRc31. The third and fourth memory devices may be directly connected to the branch point BRc32. The fifth and sixth memory devices may be directly connected to the branch point BRc33. The seventh and eighth memory devices may be directly connected to the branch point BRc34.

In the storage device SD, the wire of the continuous T-shaped branch structure may be vulnerable to the noise. For example, the device controller may determine the first memory device among the first to eighth memory devices as a target memory device and may provide a signal to the target memory device. A main component of the signal may move to the branch point BRc21, at which the target memory device exists, through the branch point BRc1, but the remaining components of the signal may be reflected at the branch point BRc1 as noise components or may be distributed to the branch point BRc22 at which the target memory device does not exist. The main component may be further reflected at the branch points BRc21 and BRc31 or may be further distributed. Because the wire of the continuous T-shaped branch structure causes the reflection or the distribution by the sequential branches, the wire of the continuous T-shaped branch structure may be vulnerable to the noise.

In addition, a reflection path of the noise components may become longer on the wire of the continuous T-shaped branch structure. For example, one of the noise components may arrive at the eighth memory device sequentially through the branch points BRc1, BRc22, and BRc34, may be reflected from the eighth memory device, and may arrive at the first memory device sequentially through the branch points BRc34, BRc22, BRc1, BRc21, and BRc31. Because the reflection path is long, even after the main component of the signal is processed in the first memory device, the noise components of the signal may have an influence on the first memory device during a long time.

Also, the noise components reflected from the second to eighth memory devices to the branch points BRc31, BRc32, BRc33, and BRc34 may be suppressed by adjusting termination resistance values by on die termination (ODT) functions of the second to eighth memory devices, but it may be difficult to adjust the noise components at the branch points BRc21 and BRc22 corresponding to the second branch.

As described above, according to the wire of the continuous T-shaped branch structure of the storage device SD, because a signal is transmitted through a plurality of branch points, the noise components by the reflection or distribution may frequently occur, and the influence of the noise components due to the long reflection path may be maintained during a long time, and it may be difficult to adjust the noise components at some branch points by using the ODT function.

Because the minimum quality of signal is required for the normal transmission of a data signal, the noise components may hinder a high-speed input/output (I/O) operation or may make low-power driving (e.g., an operation of a low tapped termination (LTT) mode) using a small voltage swing difficult.

FIG. 4 is a block diagram describing an example of a storage device according to some implementations. In FIG. 4, the storage device 100 may connect a plurality of memory devices to one device controller 111 to provide a large storage capacity. For example, the storage device 100 may include the device controller 111 and first to eighth memory devices 121 to 128. The device controller 111 may be connected to the first to eighth memory devices 121 to 128 through a ring wire. The ring wire may have a closed loop structure.

The device controller 111 may be directly connected to a main branch point BRm of the ring wire. The first and second memory devices 121 and 122 may be directly connected to a first branch point BR1 of the ring wire. The third and fourth memory devices 123 and 124 may be directly connected to a second branch point BR2 of the ring wire. The fifth and sixth memory devices 125 and 126 may be directly connected to a third branch point BR3 of the ring wire. The seventh and eighth memory devices 127 and 128 may be directly connected to a fourth branch point BR4 of the ring wire. That is, the ring wire may have the closed loop structure including the main branch point BRm, the first branch point BR1, the second branch point BR2, the third branch point BR3, and the fourth branch point BR4.

In the storage device 100 of the present disclosure, the ring wire of the closed loop structure may be robust against the noise. For example, the device controller 111 may determine the first memory device 121 among the first to eighth memory devices 121 to 128 as a target memory device and may provide a signal to the target memory device. A main component of the signal may arrive at the target memory device through the main branch point BRm and the first branch point BR1. An auxiliary component distributed at the main branch point BRm may arrive at the target memory device sequentially through the fourth branch point BR4, the third branch point BR3, the second branch point BR2, and the first branch point BR1.

In this case, in the ring wire of the closed loop structure, a transmission path of the auxiliary component may be shorter than the reflection path of the noise component in the wire of the continuous T-shaped branch structure of FIG. 3. For example, the auxiliary component distributed from the main branch point BRm to the fourth branch point BR4 may arrive at the first memory device 121 sequentially through the third, second, and first branch points BR3, BR2, and BR1. Because the auxiliary component arrives at the first memory device 121 within a short time, the auxiliary component may reinforce the waveform of the main component to be identified in the first memory device 121, not applied to the main component as the noise component.

Also, the noise component to be reflected from the second memory device 122 to the first branch point BR1 may be suppressed by adjusting the termination reference value by the ODT function of the second memory device 122. As in the above description, the noise components at the second branch point BR2 may be suppressed by the ODT functions of the third and fourth memory devices 123 and 124. The noise components at the third branch point BR3 may be suppressed by the ODT functions of the fifth and sixth memory devices 125 and 126. The noise components at the fourth branch point BR4 may be suppressed by the ODT functions of the seventh and eighth memory devices 127 and 128. That is, unlike the noise components at the branch points BRc21 and BRc22 of FIG. 3, the noise components at the first to fourth branch points BR1 to BR4 of the ring wire may be easily suppressed by the ODT functions.

As described above, according to the ring wire of the closed loop structure of the storage device 100 of the present disclosure, the auxiliary component distributed from the main branch point BRm may arrive at the target memory device through a short transmission path, and thus, the auxiliary component may reinforce the waveform of the main component, not applied as the noise component. Because memory devices are directly connected to the ring wire, the memory devices may easily suppress the noise component by using the ODT function.

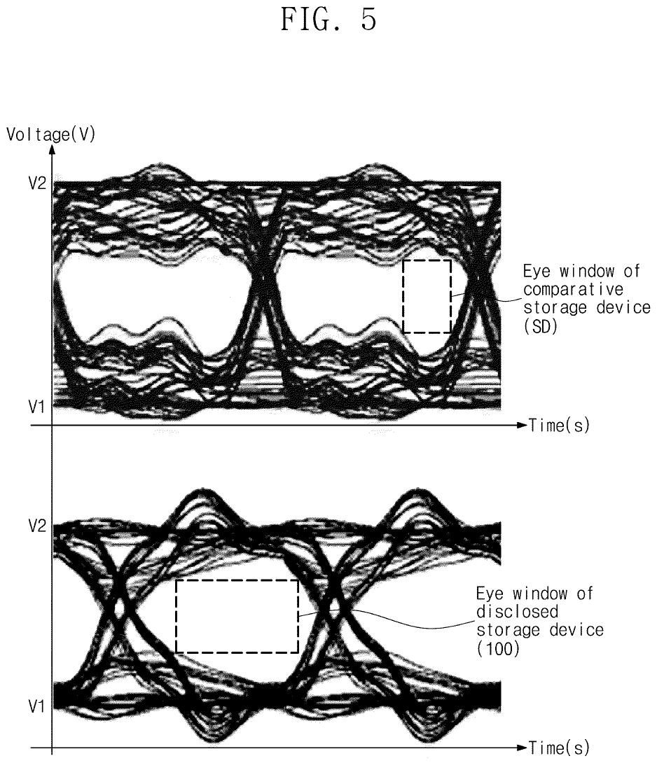

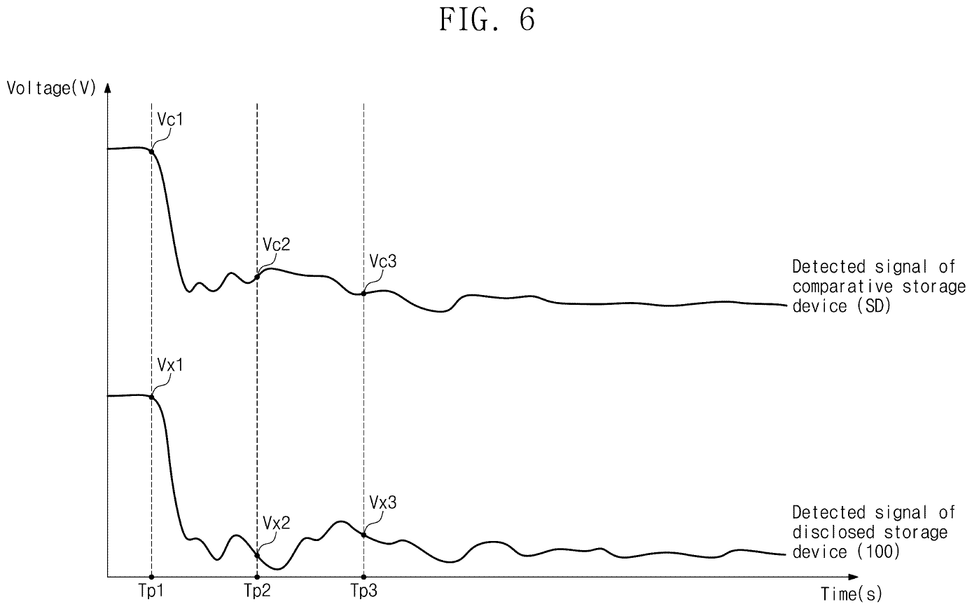

In other words, a transmission path of a distributed signal may become shorter based on the physical structure of the ring wire, and the noise at a branch point of the ring wire may be suppressed based on the ODT function. According to the above description, the storage device 100 may reduce the signal distortion, may increase the integrity of signal, may support the high-speed I/O operation, and may make the low-power driving (e.g., the operation of the LTT mode) using the small voltage swing easy. The signal characteristic of the storage device 100 will be described in detail with reference to FIGS. 5 and 6.

FIG. 5 is a graph describing an example of an eye window of a storage device according to some implementations. For better understanding of the present disclosure, the storage device SD and the storage device 100 of the present disclosure will be described together. The storage device SD may correspond to the storage device SD of FIG. 3. The storage device 100 may correspond to the storage device 100 of FIG. 4. In a graph, the horizontal axis represents a time, and the vertical axis represents a voltage level. The eye window of the storage device SD and the eye window of the disclosed storage device 100 will be described with reference to FIGS. 3, 4, and 5.

The storage device SD may include a device controller and first to eighth memory devices. The first memory device may be a target memory device for communicating a signal. The waveform of the storage device SD may show an example of voltage levels of a signal measured at an input terminal of the target memory device or an input terminal of the device controller. The signal may indicate a series of bit values. The signal may be designed to have a first voltage level V1 or a second voltage level V2. The first voltage level V1 may indicate a logic low level. The second voltage level V2 may indicate a logic high level.

The signal may have a voltage level different from a designed voltage level due to various factors such as reflection from the second to eighth memory devices, not the target memory device, distribution or reflection at branch points, and a signal corresponding to a previous bit value. The eye window may refer to a gap in the waveform of the signal. As the voltage level of the signal is out of the designed voltage level, the eye window in the waveform of the signal may become smaller. The horizontal length of the eye window may represent a time margin for determining a bit value. The vertical length of the eye window may represent a voltage level difference for distinguishing the logic low level and the logic high level.

As in the above description, the storage device 100 may include the device controller 111 and the first to eighth memory devices 121 to 128. The first memory device 121 may be a target memory device for communicating a signal. The waveform of the storage device 100 may show an example of voltage levels of a signal measured at an input terminal of the target memory device or an input terminal of the device controller 111. The signal may be designed to have the first voltage level V1 or the second voltage level V2.

The signal may have a voltage level different from a designed voltage level due to various factors such as reflection from the second to eighth memory devices 122 to 128, not the target memory device, distribution or reflection at branch points, and a signal corresponding to a previous bit value. The eye window may refer to a gap in the waveform of the signal.

In FIG. 5, the horizontal length of the eye window of the storage device 100 may be longer than the horizontal length of the eye window of the storage device SD. Because the storage device 100 is capable of suppressing the noise based on the ring wire of the closed loop structure, the storage device 100 may have the eye window wider than the eye window of the storage device SD. As the eye window becomes wider, the error rate of the signal may be decreased, and the signal with the wider eye window may be advantageous to the high-speed I/O operation.

FIG. 6 is a graph describing a detected signal of a storage device according to some implementations. For better understanding, the storage device SD and the storage device 100 of the present disclosure will be described together. The storage device SD may correspond to the storage device SD of FIG. 3. The storage device 100 may correspond to the storage device 100 of FIG. 4. In a graph, the horizontal axis represents a time, and the vertical axis represents a voltage level. A detected signal of the storage device SD and a detected signal of the disclosed storage device 100 will be described with reference to FIGS. 3, 4, and 6.

The storage device SD may include a device controller and first to eighth memory devices. The first memory device may be a target memory device for communicating a signal. The waveform of the storage device SD may show an example of a voltage level of a signal detected at an input terminal of the target memory device or an input terminal of the device controller. The signal may be implemented as a single pulse signal transitioning from the logic high level to the logic low level. The signal may have an influence as the noise component even after a bit value is determined, due to various factors such as reflection from the second to eighth memory devices, not the target memory device, and distribution or reflection at branch points.

For example, referring to the graph of the detected signal of the storage device SD, a first time point Tp1 may indicate a timing at which a first bit value (e.g., the logic high level) corresponding to the single pulse signal is detected. A second time point Tp2 may indicate a timing at which a second bit value (e.g., the logic low level) after one period is detected. A third time point Tp3 may indicate a timing at which a third bit value (e.g., the logic low level) after two periods are detected. At the first point Tp1, the detected signal may have a voltage level Vc1. At the second point Tp2, the detected signal may have a voltage level Vc2. At the third point Tp3, the detected signal may have a voltage level Vc3.

As in the above description, the storage device 100 may include the device controller 111 and the first to eighth memory devices 121 to 128. The first memory device 121 may be a target memory device for communicating a signal. The waveform of the storage device 100 may show an example of a voltage level of a signal detected at an input terminal of the target memory device or an input terminal of the device controller 111. The signal may be implemented as a single pulse signal. The signal may have an influence as the noise component even after a bit value is determined, due to various factors such as reflection from the second to eighth memory devices 122 to 128, not the target memory device, and distribution or reflection at branch points.

For example, in FIG. 6, the detected signal of the storage device 100, at the first time point Tp1, the detected signal may have a voltage level Vx1. At the second point Tp2, the detected signal may have a voltage level Vx2. At the third point Tp3, the detected signal may have a voltage level Vx3.

In FIG. 6, the storage device SD and the storage device 100, a difference between the voltage levels Vx1 and Vx2 of the storage device 100 may be greater than a difference between the voltage levels Vcl and Vc2 of the storage device SD. Because the first time point Tp1 corresponds to the logic high level and the second time point Tp2 corresponds to the logic low level, as a difference between voltage levels at the first and second time points Tp1 and Tp2 becomes greater, a bit value of the signal may be accurately determined. That is, in the storage device 100, the transition of the voltage level may be accurately determined.

Also, a difference between the voltage levels Vx2 and Vx3 of the storage device 100 may be smaller than a difference between the voltage levels Vc2 and Vc3 of the storage device SD. Because the second time point Tp2 corresponds to the logic low level and the third time point Tp3 corresponds to the logic low level, as a difference between voltage levels at the second and third time points Tp2 and Tp3 becomes smaller, a bit value of the signal may be accurately determined. That is, in the storage device 100, the maintenance of the voltage level may be accurately determined.

As described above, because the storage device 100 is capable of suppressing the noise based on the ring wire of the closed loop structure, voltage levels may be determined in the storage device 100 to be more accurate than in the storage device SD. That is, in the storage device 100, the distortion of signal may be decreased, and the integrity of signal may be increased.

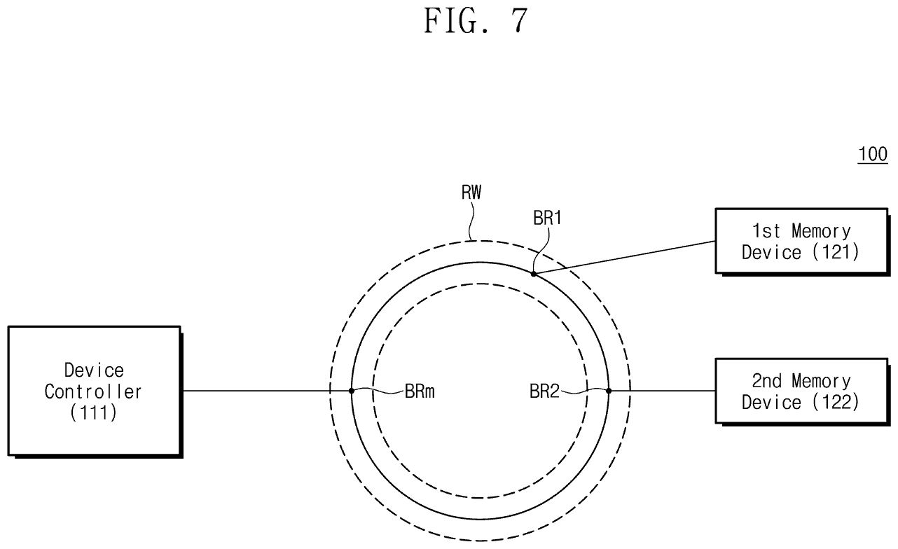

FIG. 7 is a diagram describing an example of a storage device according to some implementations. In FIG. 7, the storage device 100 may include the device controller 111, the first memory device 121, the second memory device 122, and a ring wire RW.

In FIG. 7, an example in which the ring wire RW is connected to two memories is illustrated, but the scope of the present disclosure is not limited thereto. Two or more memory devices may be connected to the ring wire RW. Two or more memory devices may be connected to one branch point of the ring wire RW. The ring wire RW is illustrated in the shape of a ring for intuitive understanding, but the ring wire RW may be implemented in the shape of a circle or a polygon.

The ring wire RW may have a closed loop structure. The ring wire RW may include the main branch point BRm, the first branch point BR1, and the second branch point BR2. The device controller 111 may be connected to the main branch point BRm of the ring wire RW. The first memory device 121 may be connected to the first branch point BR1 of the ring wire RW. The second memory device 122 may be connected to the second branch point BR2 of the ring wire RW.

The device controller 111 may manage the read operation, the write operation, and the erase operation of the first memory device 121. The first memory device 121 may include a plurality of first memory chips packaged. The device controller 111 may provide a signal to the first memory device 121 through the ring wire RW. The first memory device 121 may provide a signal to the device controller 111 through the ring wire RW. While the device controller 111 and the first memory device 121 communicate with each other, under control of the device controller 111, the second memory device 122 may suppress the noise at the second branch point BR2 based on the ODT function.

The device controller 111 may manage the read operation, the write operation, and the erase operation of the second memory device 122. The second memory device 122 may include a plurality of second memory chips packaged. The device controller 111 may provide a signal to the second memory device 122 through the ring wire RW. The second memory device 122 may provide a signal to the device controller 111 through the ring wire RW. While the device controller 111 and the second memory device 122 communicate with each other, under control of the device controller 111, the first memory device 121 may suppress the noise at the first branch point BR1 based on the ODT function.

In some implementations, the device controller 111 may provide branched components to a target memory device. For example, the device controller 111 may determine the first memory device 121 among the first and second memory devices 121 and 122 as a target memory device. The device controller 111 may generate a signal to be provided to the first memory device 121. The device controller 111 may provide a branched first component of the signal to the first memory device 121 through a first path bypassing the second branch point BR2 (e.g., a path on the ring wire RW in a clockwise direction). Also, the device controller 111 may provide a branched second component of the signal to the first memory device 121 through a second path including the second branch point BR2 (e.g., a path on the ring wire RW in an anticlockwise direction).

In this case, the second path may be implemented as a short path. For example, a component distributed or reflected in the wire of the continuous T-shaped branch structure of the storage device SD of FIG. 3 may arrive at the target memory device as the noise component through a long path. Comparatively, a component distributed in the closed loop structure of the storage device 100 arrives at the target memory device through the second path relatively short, the component distributed to the second path may reinforce the waveform of the main component to be identified by the target memory device as the auxiliary component, not as the noise component.

In some implementations, the target memory device may provide the branched components to the device controller 111. For example, the device controller 111 may determine the first memory device 121 among the first and second memory devices 121 and 122 as a target memory device. The first memory device 121 may generate a signal to be provided to the device controller 111. The first memory device 121 may provide a branched first component of the signal to the device controller 111 through the first path bypassing the second branch point BR2. Also, the first memory device 121 may provide a branched second component of the signal to the device controller 111 through the second path including the second branch point BR2.

As described above, according to some implementations, there may be provided the storage device 100 in which the distortion of signal is decreased and the integrity of signal is increased by making the transmission path of the branched signal become shorter based on the physical structure of the ring wire and suppressing the noise at the branch point of the ring wire based on the ODT function.

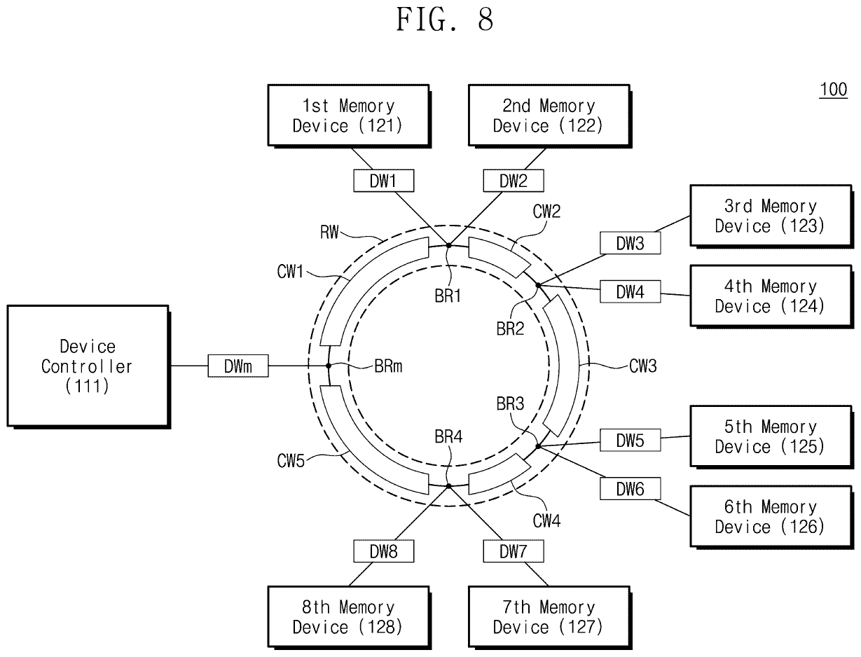

FIG. 8 is a diagram describing an example of a storage device according to some implementations. In FIG. 8, the storage device 100 may include the device controller 111, the first to eighth memory devices 121 to 128, the ring wire RW, a main device wire DWm, and first to eighth device wires DW1 to DW8. The ring wire RW may include the main branch point BRm, the first to fourth branch points BR1 to BR4, and first to fifth connection wires CW1 to CW5.

For convenience of description, the terms “ring wire”, “device wire”, “branch point”, etc. are used, but the ring wire and the device wire may refer to a connected wire of the same material, the connection wire may indicate a portion of the ring wire, and the branch point may indicate a point at which a wire is distributed to two or more paths.

When the description is given as a first component and a second component are connected, any other component interposed between the first and second components may exist, or the first and second components may be directly connected without any other component. Comparatively, when the description is given as a first component and a second component are directly connected, any other component interposed between the first and second components may not exist.

The device controller 111 may be connected to the main branch point BRm of the ring wire RW. The first and second memory devices 121 and 122 may be connected to the first branch point BR1 of the ring wire RW. The third and fourth memory devices 123 and 124 may be connected to the second branch point BR2 of the ring wire RW. The fifth and sixth memory devices 125 and 126 may be connected to the third branch point BR3 of the ring wire RW. The seventh and eighth memory devices 127 and 128 may be connected to the fourth branch point BR4 of the ring wire RW.

The main device wire DWm may be directly connected to the device controller 111 and the main branch point BR. The first device wire DW1 may be directly connected to the first memory device 121 and the first branch point BR1. The second device wire DW2 may be directly connected to the second memory device 122 and the first branch point BR1. The third device wire DW3 may be directly connected to the third memory device 123 and the second branch point BR2. The fourth device wire DW4 may be directly connected to the fourth memory device 124 and the second branch point BR2. The fifth device wire DW5 may be directly connected to the fifth memory device 125 and the third branch point BR3. The sixth device wire DW6 may be directly connected to the sixth memory device 126 and the third branch point BR3. The seventh device wire DW7 may be directly connected to the seventh memory device 127 and the fourth branch point BR4. The eighth device wire DW8 may be directly connected to the eighth memory device 128 and the fourth branch point BR4.

The ring wire RW may include the first connection wire CW1 directly connecting the main branch point BRm and the first branch point BR1. The ring wire RW may include the second connection wire CW2 directly connecting the first branch point BR1 and the second branch point BR2. The ring wire RW may include the third connection wire CW3 directly connecting the second branch point BR2 and the third branch point BR3. The ring wire RW may include the fourth connection wire CW4 directly connecting the third branch point BR3 and the fourth branch point BR4. The ring wire RW may include the fifth connection wire CW5 directly connecting the fourth branch point BR4 and the main branch point BRm.

In this case, the first to fifth connection wires CW1 to CW5 may only refer to a portion of the ring wire RW and are not intended to limit the physical shape of the ring wire RW. Each of the first to fifth connection wires CW1 to CW5 may be implemented as a straight line or a curved line. Unlike the illustrated example, the first to fifth connection wires CW1 to CW5 may be implemented to have different lengths.

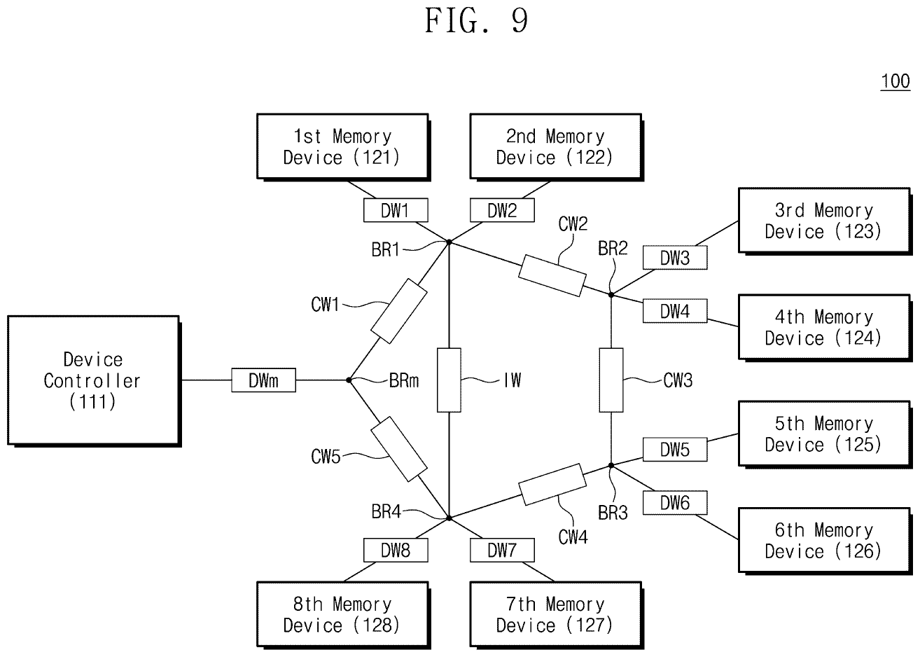

FIG. 9 is a diagram describing an example of a storage device according to some implementations. In FIG. 9, the storage device 100 may include the device controller 111, the first to eighth memory devices 121 to 128, the main device wire DWm, the first to eighth device wires DW1 to DW8, the first to fifth connection wires CW1 to CW5, and an internal wire IW. The main branch point BRm, the first to fourth branch points BR1 to BR4, and the first to fifth connection wires CW1 to CW5 may be collectively referred to as a “ring wire”.

Characteristics of the device controller 111, the first to eighth memory devices 121 to 128, the main device wire DWm, the first to eighth device wires DW1 to DW8, the first to fifth connection wires CW1 to CW5, the main branch point BRm, and the first to fourth branch points BR1 to BR4 are similar to the characteristics of the device controller 111, the first to eighth memory devices 121 to 128, the main device wire DWm, the first to eighth device wires DW1 to DW8, the first to fifth connection wires CW1 to CW5, the main branch point BRm, and the first to fourth branch points BR1 to BR4 of FIG. 8, and thus, additional description will be omitted to avoid redundancy.

In some implementations, the storage device 100 may include an internal wire partitioning a ring wire. For example, the storage device 100 may include the internal wire IW. The internal wire IW may directly connect the first branch point BR1 and the fourth branch point BR4.

An example of a location of the internal wire IW is described for better understanding of the present disclosure, but the present disclosure is not limited to the illustrated internal wire IW. The internal wire IW may be modified to directly connect two arbitrary different branch points among the branch points BRm, BR1, BR2, BR3, and BR4.

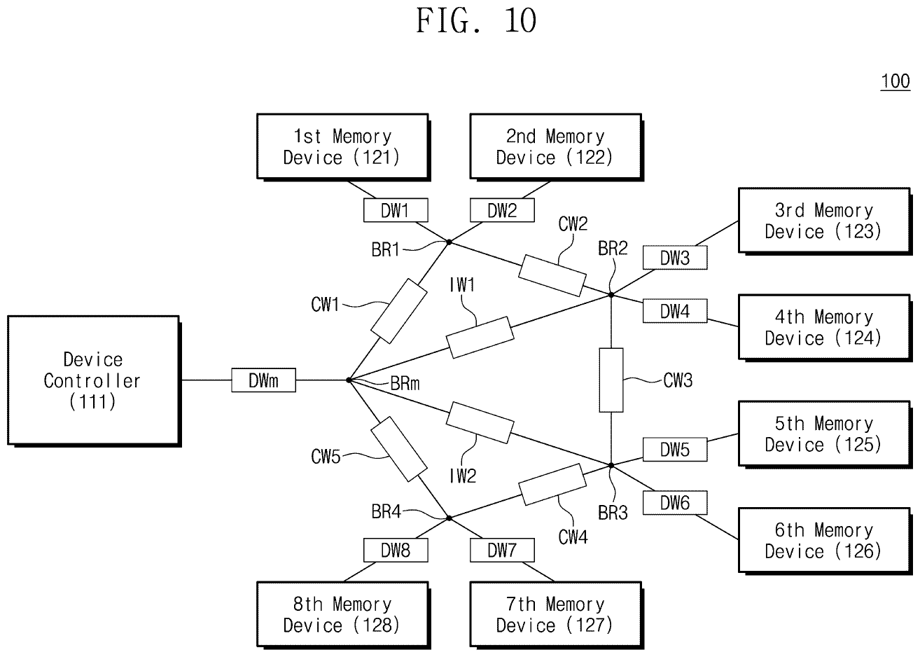

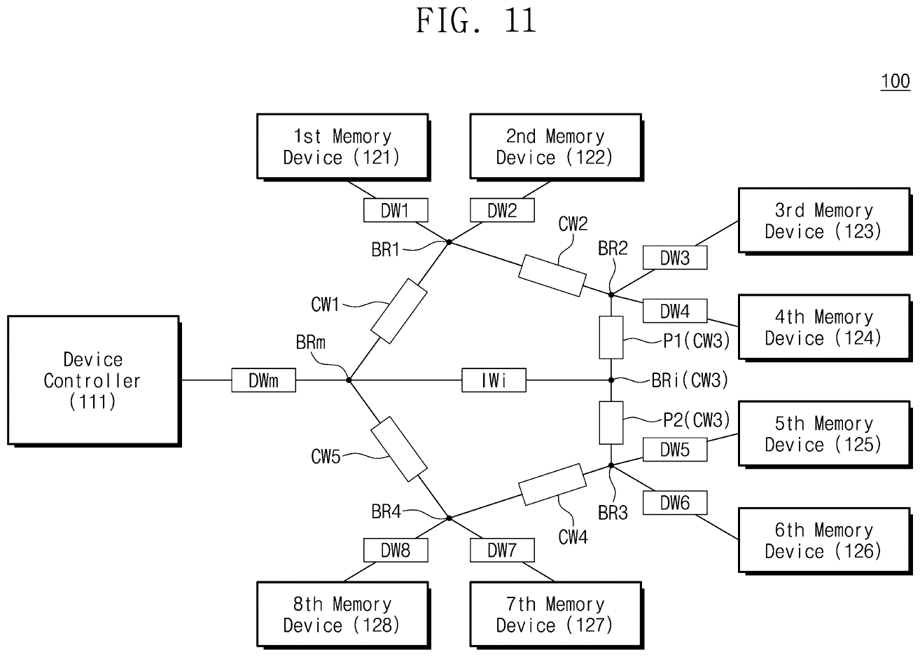

Also, the present disclosure does not exclude the presence of two or more internal wires, and a plurality of internal wires will be described with reference to FIG. 10. The present disclosure may not require that a branch point directly connected to an internal wire is directly connected to a memory device or a device wire, and an implementations in which a branch point is added by an internal wire will be described with reference to FIG. 11.

FIG. 10 is a diagram describing an example of a storage device according to some implementations. In FIG. 10, the storage device 100 may include the device controller 111, the first to eighth memory devices 121 to 128, the main device wire DWm, the first to eighth device wires DW1 to DW8, the first to fifth connection wires CW1 to CW5, and first and second internal wires IW1 and IW2. The main branch point BRm, the first to fourth branch points BR1 to BR4, and the first to fifth connection wires CW1 to CW5 may be collectively referred to as a “ring wire”.

Characteristics of the device controller 111, the first to eighth memory devices 121 to 128, the main device wire DWm, the first to eighth device wires DW1 to DW8, the first to fifth connection wires CW1 to CW5, the main branch point BRm, and the first to fourth branch points BR1 to BR4 are similar to the characteristics of the device controller 111, the first to eighth memory devices 121 to 128, the main device wire DWm, the first to eighth device wires DW1 to DW8, the first to fifth connection wires CW1 to CW5, the main branch point BRm, and the first to fourth branch points BR1 to BR4 of FIG. 8, and thus, additional description will be omitted to avoid redundancy.

In some implementations, the storage device 100 may include a plurality of internal wires partitioning a ring wire. For example, the storage device 100 may generate the first internal wire IW1 and the second internal wire IW2. The first internal wire IW1 may directly connect the main branch point BRm and the second branch point BR2. The second internal wire IW2 may directly connect the main branch point BRm and the third branch point BR3.

An example of locations of the first and second internal wires IW1 and IW2 is illustrated for better understanding of the present disclosure, but the present disclosure is not limited to the illustrated first and second internal wires IW1 and IW2. Each of the first and second internal wires IW1 and IW2 may be modified to directly connect two arbitrary different branch points among the branch points BRm, BR1, BR2, BR3, AND BR4.

FIG. 11 is a diagram describing an example of a storage device according to some implementations. In FIG. 11, the storage device 100 may include the device controller 111, the first to eighth memory devices 121 to 128, the main device wire DWm, the first to eighth device wires DW1 to DW8, the first to fifth connection wires CW1 to CW5, and an internal wire IWi. The main branch point BRm, the first to fourth branch points BR1 to BR4, and the first to fifth connection wires CW1 to CW5 may be collectively referred to as a “ring wire”. The third connection wire CW3 may include a first partial wire P1, a second partial wire P2, and an internal branch point BRi.

Characteristics of the device controller 111, the first to eighth memory devices 121 to 128, the main device wire DWm, the first to eighth device wires DW1 to DW8, the first, second, fourth, and fifth connection wires CW1, CW2, CW4, and CW5, the main branch point BRm, and the first to fourth branch points BR1 to BR4 are similar to the characteristics of the device controller 111, the first to eighth memory devices 121 to 128, the main device wire DWm, the first to eighth device wires DW1 to DW8, the first, second, fourth, and fifth connection wires CW1, CW2, CW4, and CW5, the main branch point BRm, and the first to fourth branch points BR1 to BR4 of FIG. 8, and thus, additional description will be omitted to avoid redundancy.

In some implementations, the storage device 100 may include an internal wire partitioning a ring wire, and a branch point of the ring wire may be added by the internal wire. For example, the storage device 100 may include the internal wire IWi. The internal wire IWi may be directly connected to the third connection wire CW3. As the internal wire IWi is connected to the third connection wire CW3, an internal branch point BRi may be added on the third connection wire CW3. The internal branch point BRi may indicate a location where the third connection wire CW3 is branched by the internal wire IWi and may partition the third connection wire CW3 to the first partial wire P1 and the second partial wire P2. The internal wire IWi may directly connect the main branch point BRm and the internal branch point BRi.

An example of a location of the internal wire IWi is described for better understanding of the present disclosure, but the present disclosure is not limited to the illustrated internal wire IWi. One end of the internal wire IWi may be modified to directly connect two arbitrary different branch points on the ring wire regardless of whether to correspond to the branch points BRm, BR1, BR2, BR3, and BR4.

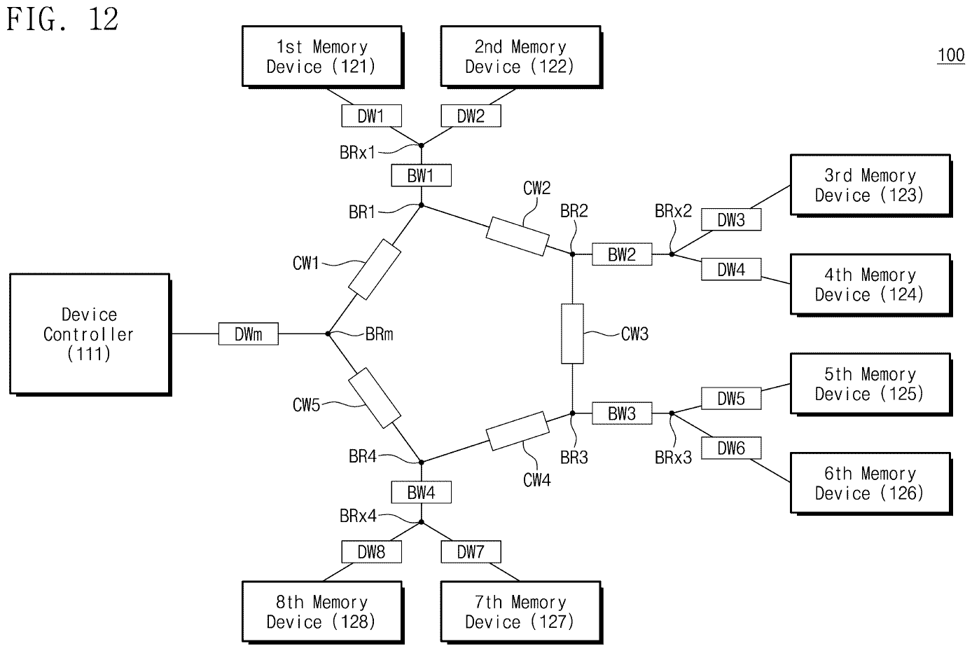

FIG. 12 is a diagram describing an example of a storage device according to some implementations. In FIG. 12, the storage device 100 may include the device controller 111, the first to eighth memory devices 121 to 128, the main device wire DWm, the first to eighth device wires DW1 to DW8, the first to fifth connection wires CW1 to CW5, and first to fourth branch wires BW1 to BW4. The main branch point BRm, the first to fourth branch points BR1 to BR4, and the first to fifth connection wires CW1 to CW5 may be collectively referred to as a “ring wire”. First to fourth additional branch points BRx1 to BRx4 may be respectively connected to the first to fourth branch wires BW1 to BW4.

In some implementations, the storage device 100 may include a wire of a T-shaped branch structure connected to a ring wire. For example, the main device wire DWm may be directly connected to the device controller 111 and the main branch point BRm. The first branch wire BW1 may be directly connected to the first branch point BR1 and the first additional branch point BRx1. The first device wire DW1 may be directly connected to the first memory device 121 and the first additional branch point BRx1. The second device wire DW2 may be directly connected to the second memory device 122 and the first additional branch point BRx1. The first device wire DW1, the second device wire DW2, and the first branch wire BW1 may be collectively referred to as a “wire of a T-shaped branch structure”. The first and second memory devices 121 and 122 may be connected to the ring wire through the wire of the T-shaped branch structure, not directly connected to the ring wire.

As in the above description, the third and fourth memory devices 123 and 124 may be connected to the second branch point BR2 of the ring wire through the wire of the T-shaped branch structure including the second additional branch point BRx2 and the wires BW2, DW3, and DW4. The fifth and sixth memory devices 125 and 126 may be connected to the third branch point BR3 of the ring wire through the wire of the T-shaped branch structure including the third additional branch point BRx3 and the wires BW3, DW5, and DW6. The seventh and eighth memory devices 127 and 128 may be connected to the fourth branch point BR4 of the ring wire through the wire of the T-shaped branch structure including the fourth additional branch point BRx4 and the wires BW4, DW7, and DW8.

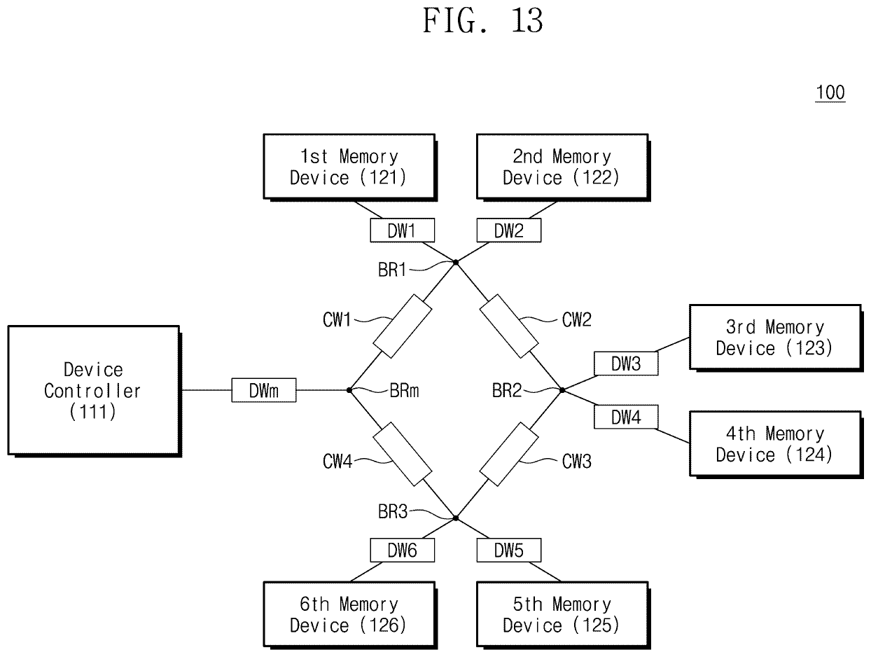

FIG. 13 is a diagram describing an example of a storage device according to some implementations. In FIG. 13, the storage device 100 may include the device controller 111, the first to sixth memory devices 121 to 126, the main device wire DWm, the first to sixth device wires DW1 to DW6, and the first to fourth connection wires CW1 to CW4. The main branch point BRm, the first to third branch points BR1 to BR3, and the first to fourth connection wires CW1 to CW4 may be collectively referred to as a “ring wire”.

The first and second memory devices 121 and 122 may be connected to the first branch point BR1 of the ring wire. The third and fourth memory devices 123 and 124 may be connected to the second branch point BR2 of the ring wire. The fifth and sixth memory devices 125 and 126 may be connected to the third branch point BR3 of the ring wire.

In some implementations, the storage device 100 may be connected to six memory devices through a ring wire. For example, the ring wire may include the first connection wire CW1 directly connecting the main branch point BRm and the first branch point BR1, the second connection wire CW2 directly connecting the first branch point BR1 and the second branch point BR2, the third connection wire CW3 directly connecting the second branch point BR2 and the third branch point BR3, and the fourth connection wire CW4 directly connecting the third branch point BR3 and the main branch point BRm.

The first memory device 121 may be directly connected to the first branch point BR1 through the first device wire DW1, and the second memory device 122 may be directly connected to the first branch point BR1 through the second device wire DW2. The third memory device 123 may be directly connected to the second branch point BR2 through the third device wire DW3, and the fourth memory device 124 may be directly connected to the second branch point BR2 through the fourth device wire DW4. The fifth memory device 125 may be directly connected to the third branch point BR3 through the fifth device wire DW5, and the sixth memory device 126 may be directly connected to the third branch point BR1 through the sixth device wire DW6.

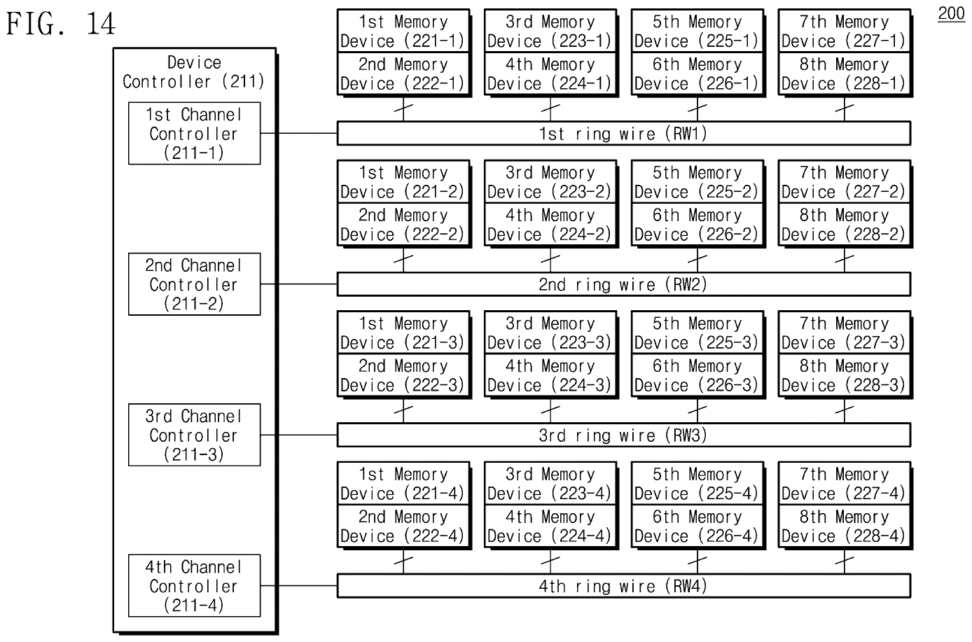

FIG. 14 is a diagram describing an example of a storage device according to some implementations. In FIG. 14, a storage device 200 may include a device controller 211, first to fourth ring wires RW1 to RW4, and a plurality of memory devices 221-1 to 228-1, 221-2 to 228-2, 221-3 to 228-3, and 221-4 to 228-4.

The device controller 211 may include first to fourth channel controllers 211-1 to 211-4. The first channel controller 211-1 may be connected to the first to eighth memory devices 221-1 to 228-1 through the first ring wire RW1. The first channel controller 211-1, the first ring wire RW1, and the first to eighth memory devices 221-1 to 228-1 may be collectively referred to as a “first memory channel”.

The first channel controller 211-1 may manage the read operation, the write operation, and the erase operation of each of the first to eighth memory devices 221-1 to 228-1. The first memory device 221-1 may include a plurality of memory chips packaged. As in the above description, each of the second to eighth memory devices 222-1 to 228-1 may include a plurality of corresponding memory chips packaged.

The first ring wire RW1 may have a closed loop structure. The first channel controller 211-1 may be connected to a main branch point of the first ring wire RW1. The first and second memory devices 221-1 and 222-1 may be connected to a first branch point of the first ring wire RW1. The third and fourth memory devices 223-1 and 224-1 may be connected to a second branch point of the first ring wire RW1. The fifth and sixth memory devices 225-1 and 226-1 may be connected to a third branch point of the first ring wire RW1. The seventh and eighth memory devices 227-1 and 228-1 may be connected to a fourth branch point of the first ring wire RW1.

As in the above description, the second channel controller 211-2 may be connected to the first to eighth memory devices 221-2 to 228-2 through the second ring wire RW2, which are collectively referred to as a “second memory channel”. The third channel controller 211-3 may be connected to the first to eighth memory devices 221-3 to 228-3 through the third ring wire RW3, which are collectively referred to as a “third memory channel”. The fourth channel controller 211-4 may be connected to the first to eighth memory devices 221-4 to 228-4 through the fourth ring wire RW4, which are collectively referred to as a “fourth memory channel”.

Each of the second to fourth memory channels may be implemented to be similar to the first memory channel. Each of the first to fourth memory channels may correspond to the storage device 100 of FIGS. 7, 8, 9, 10, 11, 12, and 13.

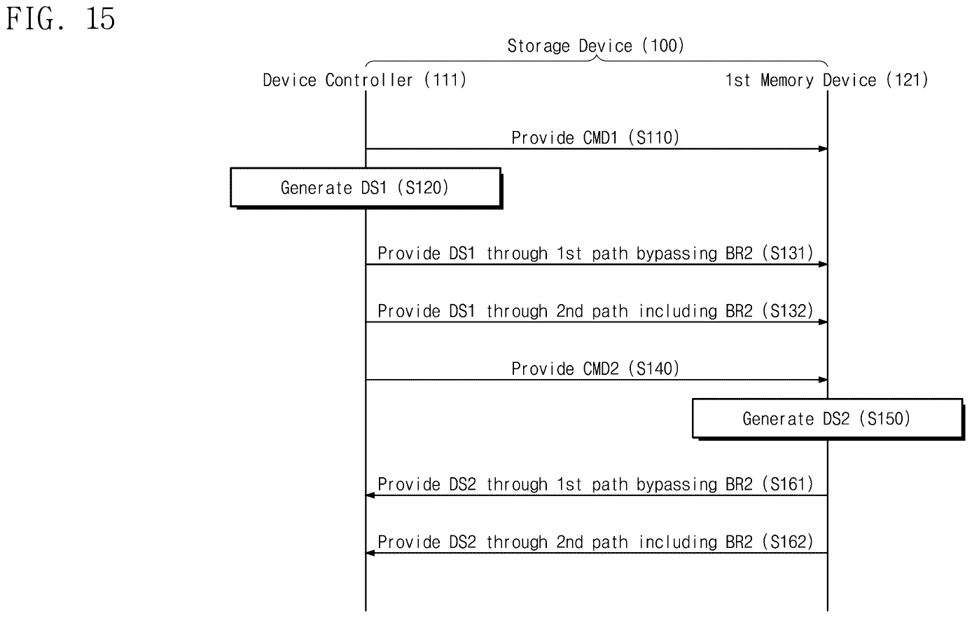

FIG. 15 is a flowchart describing a method of operating a storage device according to some implementations. A storage device may correspond to the storage device 100 of FIG. 7. In FIGS. 7 and 15, the storage device 100 may include the device controller 111, the first memory device 121, the second memory device 122, and the ring wire RW.

The ring wire RW may include the main branch point BRm, the first branch point BR1, and the second branch point BR2. The device controller 111 may be connected to the main branch point BRm of the ring wire RW. The first memory device 121 may be connected to the first branch point BR1 of the ring wire RW. The second memory device 122 may be connected to the second branch point BR2 of the ring wire RW.

In operation S110, the device controller 111 may provide a first command CMD1 to the first memory device 121. For example, the device controller 111 may provide the first memory device 121 with the first command CMD1 indicating the write operation through a separate dedicated wire different from the ring wire RW. The device controller 111 may provide the first memory device 121 with a first address indicating a location where the first command CMD1 will be performed.

In operation S120, the device controller 111 may generate a first data signal DS1 corresponding to the first command CMD1. The first data signal DS1 may be an electrical signal indicating a series of bit values to be stored in the first memory device 121 depending on the write operation.

In operation S131, the device controller 111 may provide a branched first component of the first data signal DS1 to the first memory device 121 through a first path on the ring wire. The first path may bypass the second branch point BR2. For example, the first path may include the main branch point BRm and the first branch point BR1.

In operation S132, the device controller 111 may provide a branched second component of the first data signal DS1 to the first memory device 121 through a second path on the ring wire. The second path may include the second branch point BR2. For example, the second path may pass through the main branch point BRm, the second branch point BR2, and the first branch point BR1.

In operation S140, the device controller 111 may provide a second command CMD2 to the first memory device 121. For example, the device controller 111 may provide the first memory device 121 with the second command CMD2 indicating the read operation through a separate dedicated wire different from the ring wire RW. The device controller 111 may provide the first memory device 121 with a second address indicating a location where the second command CMD2 will be performed.

In operation S150, the first memory device 121 may generate a second data signal DS2 corresponding to the second command CMD2. The second data signal DS2 may be generated based on data stored in the first memory device 121. The second data signal DS2 may be an electrical signal indicating a series of bit values to be provided to the device controller 111 depending on the read operation.

In operation S161, the first memory device 121 may provide a branched third component of the second data signal DS2 to the device controller 111 through the first path on the ring wire. The first path may bypass the second branch point BR2.

In operation S162, the first memory device 121 may provide a branched fourth component of the second data signal DS2 to the device controller 111 through the second path on the ring wire. The second path may include the second branch point BR2.

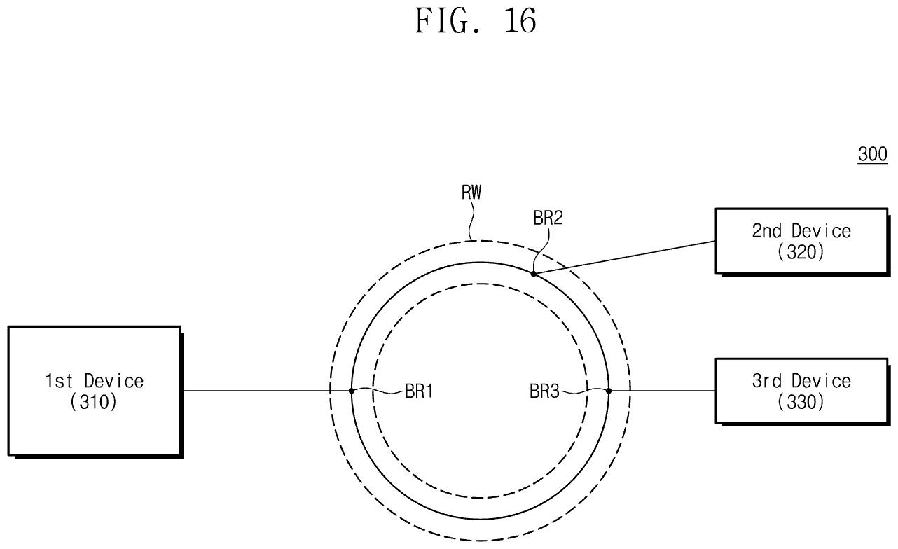

FIG. 16 is a diagram describing an example of a storage device according to some implementations. In FIG. 16, a storage device 300 may include a first device 310, a second device 320, a third device 330, and the ring wire RW. The ring wire RW may have a closed loop structure. The ring wire RW may include the first branch point BR1, the second branch point BR2, and the third branch point BR3.

The first device 310 may be implemented as a device controller or a memory device. The first device 310 may be connected to the first branch point BR1 of the ring wire RW.

The second device 320 may be implemented as a device controller or a memory device. The second device 320 may be connected to the second branch point BR2 of the ring wire RW.

The third device 330 may be implemented as a device controller or a memory device. The third device 330 may be connected to the third branch point BR3 of the ring wire RW.

According to some implementations, a storage device including a ring wire and a method of operating the same are provided.

Also, a storage device in which the distortion of signal is decreased and the integrity of signal is increased by making a transmission path of a branched signal become shorter based on a physical structure of the ring wire and suppressing the noise at a branch point of the ring wire based on an on die termination (ODT) function and a method of operating the same are provided.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A storage device comprising:
a ring wire;
a device controller connected to a main branch point of the ring wire;
a first memory device connected to a first branch point of the ring wire; and
a second memory device connected to a second branch point of the ring wire.

2. The storage device of claim 1, wherein the device controller is configured to:
generate a first data signal;
provide the first memory device with a branched first component of the first data signal through a first path that bypasses the second branch point; and
provide the first memory device with a branched second component of the first data signal through a second path including the second branch point.

3. The storage device of claim 1, wherein the first memory device is configured to:
generate a second data signal;
provide the device controller with a branched first component of the second data signal through a first path that bypasses the second branch point; and
provide the device controller with a branched second component of the second data signal through a second path including the second branch point.

4. The storage device of claim 1, comprising:
a third memory device connected to a third branch point of the ring wire; and
a fourth memory device connected to a fourth branch point of the ring wire.

5. The storage device of claim 4, comprising:
a fifth memory device connected to the first branch point;
a sixth memory device connected to the second branch point;
a seventh memory device connected to the third branch point; and
an eighth memory device connected to the fourth branch point.

6. The storage device of claim 5, comprising:
a main device wire directly connecting the device controller and the main branch point;
a first device wire directly connecting the first memory device and the first branch point;
a second device wire directly connecting the second memory device and the second branch point;
a third device wire directly connecting the third memory device and the third branch point;
a fourth device wire directly connecting the fourth memory device and the fourth branch point;
a fifth device wire directly connecting the fifth memory device and the first branch point;
a sixth device wire directly connecting the sixth memory device and the second branch point;
a seventh device wire directly connecting the seventh memory device and the third branch point; and
an eighth device wire directly connecting the eighth memory device and the fourth branch point.

7. The storage device of claim 4, wherein the ring wire includes:
a first connection wire directly connecting the main branch point and the first branch point;
a second connection wire directly connecting the first branch point and the second branch point;
a third connection wire directly connecting the second branch point and the third branch point;
a fourth connection wire directly connecting the third branch point and the fourth branch point; and
a fifth connection wire directly connecting the fourth branch point and the main branch point.

8. The storage device of claim 7, comprising an internal wire directly connecting the first branch point and the fourth branch point.

9. The storage device of claim 7, comprising:
a first internal wire directly connecting the main branch point and the second branch point; and
a second internal wire directly connecting the main branch point and the third branch point.

10. The storage device of claim 7, wherein the third connection wire includes an internal branch point, and
wherein the storage device comprises an internal wire directly connecting the main branch point and the internal branch point.

11. The storage device of claim 1, comprising:
a third memory device connected to the first branch point;
a branch wire directly connecting the first branch point and an additional branch point;
a first device wire directly connecting the first memory device and the additional branch point; and
a second device wire directly connecting the third memory device and the additional branch point.

12. The storage device of claim 1, comprising:
a third memory device connected to a third branch point of the ring wire,
wherein the ring wire includes:
a first connection wire directly connecting the main branch point and the first branch point;
a second connection wire directly connecting the first branch point and the second branch point;
a third connection wire directly connecting the second branch point and the third branch point; and
a fourth connection wire directly connecting the third branch point and the main branch point.

13. The storage device of claim 12, comprising:
a fourth memory device connected to the first branch point;
a fifth memory device connected to the second branch point; and
a sixth memory device connected to the third branch point.

14. The storage device of claim 1, wherein the device controller manages a read operation, a write operation, and an erase operation of each of the first memory device and the second memory device,
wherein the first memory device includes a plurality of first memory chips packaged, and
wherein the second memory device includes a plurality of second memory chips packaged.

15. A storage device comprising:
a device controller including a first channel controller and a second channel controller;
a first ring wire including a first main branch point connected to the first channel controller;
a first memory device connected to a first branch point of the first ring wire;
a second memory device connected to a second branch point of the first ring wire;
a second ring wire including a second main branch point connected to the second channel controller;
a third memory device connected to a third branch point of the second ring wire; and
a fourth memory device connected to a fourth branch point of the second ring wire.

16. The storage device of claim 15,
wherein the device controller includes a third channel controller and a fourth channel controller, and
wherein the storage device comprises:
a third ring wire including a third main branch point connected to the third channel controller;
a fifth memory device connected to a fifth branch point of the third ring wire;
a sixth memory device connected to a sixth branch point of the third ring wire;
a fourth ring wire including a fourth main branch point connected to the fourth channel controller;
a seventh memory device connected to a seventh branch point of the fourth ring wire; and
an eighth memory device connected to an eighth branch point of the fourth ring wire.

17. The storage device of claim 15,
wherein the first channel controller is configured to manage a read operation, a write operation, and an erase operation of each of the first memory device and the second memory device,
wherein the first memory device includes a plurality of first memory chips packaged together,
wherein the second memory device includes a plurality of second memory chips packaged together,
wherein the second channel controller is configured to manage a read operation, a write operation, and an erase operation of each of the third memory device and the fourth memory device,
wherein the third memory device includes a plurality of third memory chips packaged together, and
wherein the fourth memory device includes a plurality of fourth memory chips packaged together.

18. A method of operating a storage device that includes a ring wire, a device controller, a first memory device, and a second memory device, the method comprising:
providing, using the device controller, a first command to the first memory device;
generating, using the device controller, a first data signal corresponding to the first command;
providing, using the device controller, the first memory device with a branched first component of the first data signal through a first path on the ring wire, wherein the ring wire includes a main branch point connected to the device controller, a first branch point connected to the first memory device, and a second branch point connected to the second memory device, and the first path bypasses the second branch point; and
providing, using the device controller, the first memory device with a branched second component of the first data signal through a second path on the ring wire,
wherein the second path includes the second branch point.

19. The method of claim 18, comprising:
providing, using the device controller, a second command to the first memory device;
generating, using the first memory device, a second data signal corresponding to the second command;
providing, using the first memory device, the device controller with a branched third component of the second data signal through the first path; and
providing, using the first memory device, the device controller with a branched fourth component of the second data signal through the second path.

20. The method of claim 18,
wherein the device controller is configured to manage a read operation, a write operation, and an erase operation of each of the first memory device and the second memory device,
wherein the first memory device includes a plurality of first memory chips packaged together, and
wherein the second memory device includes a plurality of second memory chips

21. (canceled)
